(19) United States
(12) Patent Application Publication
(10) Pub. No.: US 2010/0224896 A1
(43) Pub. Date: Sep. 9, 2010

(54) LIGHT EMITTING DEVICE COMPRISING A COMPOSITE SIALON-BASED CERAMIC MATERIAL

(75) Inventors: Peter Schmidt, Aachen (DE); Andreas Tuecks, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/675,987

(22) PCT Filed: Aug. 29, 2008
(86) PCT No.: PCT/IB2008/053507

§ 371 Date: May 18, 2010

(30) Foreign Application Priority Data
Sep. 4, 2007 (EP) 07115592.3

(51) Int. Cl. H01L 33/44

(52) U.S. Cl. 257/98; 257/E33.061

(57) ABSTRACT

The invention relates to a light emitting device, especially a LED with a ceramic composite material essentially of the composition M_{1-y}A₂₋ₓBₓO₂₋₂ₓN_{2+X}:Eu_{y}, where M is selected out of the group comprising Sr, Ca, Ba, Mg or mixtures thereof, A is selected out of the group comprising Si, Ge or mixtures thereof, B is selected out of the group comprising Al, B, Ga or mixtures thereof and x and y are independently selected from >0 to ≦1. This material has been found to be a two-phase composition, one phase being an amber to red emitting phase, the other one being a cyan to green emitting phase.

### FIELD OF THE INVENTION

The present invention is directed to light emitting devices, especially to the field of LEDs.

### BACKGROUND OF THE INVENTION

In today's white emitting LEDs, usually red and green emitting luminescence conversion materials are present. These components are used in most applications as separate components.

At present there are many attempts being made to substitute these two components by a single component which is able to emit light in the desired wavelength range.

However, there is a continuing need for new components which are able to emit light over a broad wavelength range in order to make the manufacture of LEDs easier.

### SUMMARY OF THE INVENTION

It is an object of the present invention to provide a light emitting device with a converter material which is able to emit light over a broad wavelength range.

This object is achieved by means of a light emitting device according to claim 1 of the present invention. Said light emitting device especially is a LED comprising a ceramic composite material essentially of the composition M_{1-y}A₂₋ₓBₓO₂₋₂ₓN₂₊ₓ:Eu_{y}, where M is selected out of the group comprising Sr, Ca, Ba, Mg or mixtures thereof, A is selected out of the group comprising Si, Ge or mixtures thereof, B is selected out of the group comprising Al, B, Ga or mixtures thereof and x and y are independently selected from >0 to ≦1.

The term “composite” especially means and/or includes that the material is comprised of at least two different phases with different compositions (as will be described in more detail later on) which jointly form an overall composition as described. The ceramic composite material may be either directly attached to the light emitting device like a LED or the ceramic composite material may be placed at a certain distance from the light emitting device like a LED. The latter means there is no direct contact between the surface of the light emitting device and the ceramic composite material.

The term “essentially” means especially that ≧95%, preferably ≧97% and most preferred ≧99% of the material has the desired composition.

The term “ceramic material” in the sense of the present invention means and/or includes especially a crystalline or polycrystalline compact material or composite material with a controlled amount of pores or without any pores.

The term “polycrystalline material” in the sense of the present invention means and/or includes especially a material with a volume density larger than 90 percent of the main constituent, consisting for more than 80 percent of single crystal domains, with each domain being larger than 0.5 μm in diameter and possibly having different crystallographic orientations. The single crystal domains may be interconnected by amorphous or glassy material or by additional crystalline constituents.

Such a material has shown to have, for a wide range of applications within the present invention, at least one of the following advantages:
The material is able to absorb light in a wavelength range of more than 250 nm, for many applications even in a range of 400 or 470 nm.
The luminescence properties of the composite ceramic can be tuned in a wide range (as will be described later on).
The material has usually a very high (photo) thermal stability.

According to a preferred embodiment of the present invention, the composite material comprises at least one amber to red emitting phase and at least one cyan to green emitting phase. By virtue thereof, it has been found that the wavelength range of the material in the visible spectrum can be greatly enhanced for many applications.

According to a preferred embodiment of the present invention x is ≦0.6. This has been found to be advantageous for many applications, since the ratio of the amber to red emitting phase(s) and the cyan to green emitting phase(s) is usually such that the material will show a broad emission band in the visible spectral area.

Preferably, x is ≧0.01 and ≦0.5, more preferably ≦0.01 and ≦0.4.

According to a preferred embodiment of the present invention, the composite material comprises a phase of composition M(A,B)₂(O,N)₃:Eu and a phase of composition MA₂O₂N₂:Eu.

Surprisingly, it has been found for many applications that many inventive composite materials can be made comprising these two phases and that these two phases can even be found when high-temperature steps (e.g. high temperature sintering) are used. Without being bound to any theory, the inventors believe that trivalent B cations from the M(A,B)₂(O,N)₃ phase are not (or only to a very small extent) built in the MA₂O₂N₂ lattice, therefore these two phases can coexist separately in the composite material.

According to a preferred embodiment of the present invention, at least one amber to red emitting phase and/or at least one cyan to green emitting phase are essentially present in the composite material in form of ceramic grains.

According to a preferred embodiment of the present invention, the d₅₀ of the grains of

at least one amber to red emitting phase and/or least one cyan to green emitting phase is ≧3 μm to ≦50 μm. By virtue thereof, for many applications, the lighting features as well as the stability of the inventive composite ceramic can be improved.

According to a preferred embodiment of the present invention, the average grain size of the grains of the amber to red emitting phase is larger than the average grain size of the grains of the at least one cyan to green emitting phase. By virtue thereof, the amber to red emitting material will in many applications be dispersed within the composite ceramic.

Preferably, the d₅₀ of the grain size of the grains of at least one amber to red emitting phase is ≧2 μm larger, preferably ≧10 μm larger than the d₅₀ of the grain size of the grains of the at least one cyan to green emitting phase.

According to a preferred embodiment of the present invention, the emission maximum of the ceramic composite material is in the range of ≧520 nm to ≦650 nm

According to a preferred embodiment of the present invention, the half-width of the emission band of the material in the visible wavelength range is in the range of ≧90 nm to ≦160 nm.

It should be noted that within a wide range it is possible to “tune” the emission maximum as well as the half-width of the emission band of the material in the visible wavelength range by selecting the amount of amber to red emitting material in the composite ceramic.

Furthermore, it has surprisingly been shown that the emission spectrum of the cyan to green emitting MA₂O₂N₂:Eu (M=Sr, Ca, Ba, Mg; A=Si, Ge) ceramic grains may for a wide range of applications be tuned by varying the M content of the material. The larger the average ionic radius of the M cations, the more blue-shifted the emission may be. The emission maximum thus can in practice be tuned from 490 nm to 570 nm for a wide range of applications.

The emission spectrum of the amber to red emitting M(A,B)₂(O,N)₃:Eu ceramic grains may be tuned, also for a wide range of applications, by varying the M content of the material. The larger the average ionic radius of the M cations, the more blue-shifted the emission may be. The emission maximum thus can in practice be tuned from 600 nm to 670 nm for a wide range of applications.

In addition, it has been found for many applications that the spectra of the constituent phases of the composite ceramic may be tuned by changing the Eu concentration. A higher Eu concentration leads to an overall red shift of the composite material emission bands.

Preferably, y [which is the Eu content] is ≧0.001 and ≦0.05, preferably ≧0.002 and ≦0.01

According to a preferred embodiment of the present invention, the photothermal stability of the ceramic composite material is in the range of ≦80% to ≦100% after exposure of the ceramic material for 1000 hrs at 200° C. with a light power density of 10 W/cm² and an average photon energy of 2.75 eV.

The term “photothermal stability” in the sense of the present invention especially means and/or includes the conservation of the luminescence intensity under simultaneous application of heat and high intensity excitation, i.e. a photothermal stability of 100% indicates that the material is virtually unaffected by the simultaneous irradiation and heat up.

According to a preferred embodiment of the present invention, the photothermal stability of the ceramic composite material is in the range of ≧82.5% to ≦95%, preferably ≧85% to ≦97%, after exposure of the ceramic material for 1000 hrs at 200° C. with a light power density of 10 W/cm² and an average photon energy of 2.75 eV.

According to a preferred embodiment of the present invention, the thermal conductivity of the ceramic composite material is in the range of ≧0.02 W cm⁻¹ K⁻¹ to ≦0.30 W cm⁻¹ K⁻¹.

According to one embodiment of the present invention, the ceramic composite material shows a transparency at normal incidence in air in the range of ≧10% to ≦85% for light in the wavelength range from ≧550 nm to ≦1000 nm.

Preferably, the transparency for normal incidence in air is in the range of ≧20% to ≦80% for light in the wavelength range from ≧550 nm to ≦1000 nm, more preferably in the range of ≧30% to ≦75% and most preferably in the range of >40% to <70% for light in the wavelength range from ≧550 nm to ≦1000 nm.

The term “transparency” in the sense of the present invention means especially that

≧10% preferably ≧20%, more preferably ≧30%, most preferably ≧40% and ≦85% of the incident light of a wavelength, which cannot be absorbed by the material, is transmitted through the sample for normal incidence in air (at an arbitrary angle). This wavelength is preferably in the range of ≧550 nm and ≦1000 nm.

According to a preferred embodiment of the present invention, the ceramic composite material has a density in the range of ≧95% and ≦101% of the theoretical density.

According to a preferred embodiment of the present invention, the ceramic composite material has a density of ≧97% and ≦100% of the theoretical density.

The present invention furthermore relates to a method of producing a ceramic composite material for a light emitting device according to the present invention comprising a sintering step.

The term “sintering step” in the sense of the present invention means especially densification of a precursor powder under the influence of heat, which may be combined with the application of uniaxial or isostatic pressure, without reaching the liquid state of the main constituents of the sintered material.

According to a preferred embodiment of the present invention, the sintering step is pressureless, preferably in a reducing or inert atmosphere.

According to a preferred embodiment of the present invention, the method furthermore comprises the step of pressing the ceramic composite precursor material to ≧50% and ≦70%, preferably ≧55% and ≦65%, of its theoretical density before sintering. It has been shown in practice that this improves the sintering steps for most ceramic composite materials as described with respect to the present invention.

According to a preferred embodiment of the present invention, the method of producing a ceramic composite material for a light emitting device according to the present invention comprises the following steps:
(a) Mixing the precursor materials for the ceramic composite material
(b) optional firing of the precursor materials, preferably at a temperature in the range of ≧1300° C. to ≦1700° C. to remove volatile materials (such as CO₂ in case carbonates are used)
(c) optional grinding and washing
(d) a first pressing step, preferably a uniaxial pressing step using a suitable powder-compacting tool with a mould in the desired shape (e.g. rod- or pellet-shape) and/or a cold isostatic pressing step preferably at ≧3000 bar and ≦5000 bar.
(e) a sintering step at ≧1400° C. and ≦2200° C. in an inert, reducing or slightly oxidizing atmosphere with a pressure of ≧10⁻⁷ mbar and ≦10⁴ mbar.
(f) an optional hot pressing step, preferably a hot isostatic pressing step preferably at ≧30 bar and ≦2500 bar and preferably at a temperature in the range of ≧1300° C. to ≦1700° C. and/or a hot uniaxial pressing step preferably at ≧100 bar to ≦2500 bar and preferably at a temperature in the range of ≦1300° C. to ≦2000° C.
(g) optionally, a post-annealing step at >1000° C. and <1700° C. in an inert atmosphere or in a hydrogen containing atmosphere.

According to this method, for most desired material compositions, this production method has produced the best ceramic composite materials, as used in the present invention.

A light emitting device according to the present invention as well as a ceramic composite material as produced with the present method may be of use in a broad variety of systems and/or applications, amongst them one or more of the following:
Office lighting systems
household application systems
shop lighting systems,
home lighting systems,
accent lighting systems,
spot lighting systems,
theater lighting systems,
fiber-optics application systems,
projection systems,
self-lit display systems,
pixelated display systems,
segmented display systems,
warning sign systems,
medical lighting application systems,
indicator sign systems, and
decorative lighting systems
portable systems
automotive applications
green house lighting systems

The aforementioned components, as well as the claimed components and the components to be used in accordance with the invention in the described embodiments, are not subject to any special exceptions with respect to their size, shape, material selection and technical concept, so that the selection criteria known in the pertinent field can be applied without limitations.

### BRIEF DESCRIPTION OF THE DRAWINGS

Additional details, features, characteristics and advantages of the object of the invention are disclosed in the subclaims, the figures and the following description of the respective figures and examples, which—in an exemplary fashion—show several embodiments and examples of a ceramic composite material for use in a light emitting device according to the invention.

FIG. 1 shows an emission spectrum for a composite ceramic material according to Example I of the present invention at 430 nm excitation

FIG. 2 shows an emission spectrum for a composite ceramic material according to Example I of the present invention at 470 nm excitation.

FIG. 3 shows an emission spectrum for a composite ceramic material according to Example II of the present invention at 430 nm excitation.

FIG. 4 shows an emission spectrum for a composite ceramic material according to Example II of the present invention at 470 nm excitation.

FIG. 5 shows a picture of a composite ceramic wafer of Example I under UV-light.

### EXAMPLES I to II

The invention will be better understood by referring to Examples Ito IV which—in a merely illustrative fashion—are four Examples of inventive ceramic composite materials.

Example I refers to Sr₄CaSi₉AlO₈N₁₁:Eu (2%), which was made in the following way:
(a) 4.304 g AlN powder, 4.991 g Ca₃N₂ powder, 4.496 g Si₃N₄ powder and 0.352 g Eu₂O₃ powder are mixed in dry tetrahydrofuran, dried and fired in a forming gas (5% H₂ in nitrogen) twice at 1650° C. The powder cake is crushed and milled by ball milling to an average particle size of 15-20 μm.
(b) 59.048 g SrCO₃ powder, 12.017 g SiO₂ powder, 28.393 g Si₃N₄ powder and 1.408 g Eu₂O₃ powder are ball-milled in isopropanol, dried and fired in nitrogen twice at 1350° C. The powder is then ball-milled for 4 hrs and screened using a 12 μm sieve.

Powders (a) and (b) are wet-mixed by planetary ball milling with cyclohexane, and dried. The powder mixture is then pressed in a boron nitride-coated graphite die at 1500° C. in a vacuum for 4 hrs. After annealing at 1400° C. in a H₂/N₂ atmosphere, the composite ceramic is then sliced and polished to a thickness of 100 μm.

Example II was made in analogous fashion, except that for Example II only 44.4 wt % of Powder (b) was used.

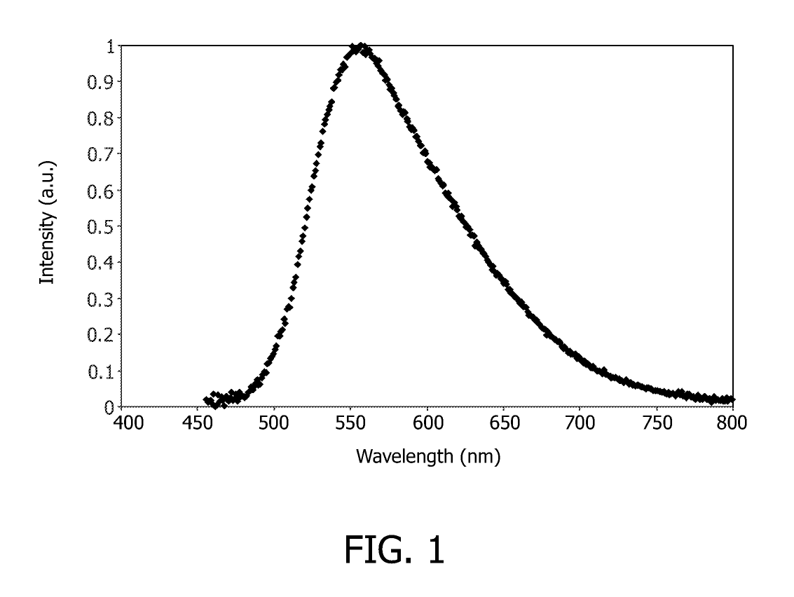

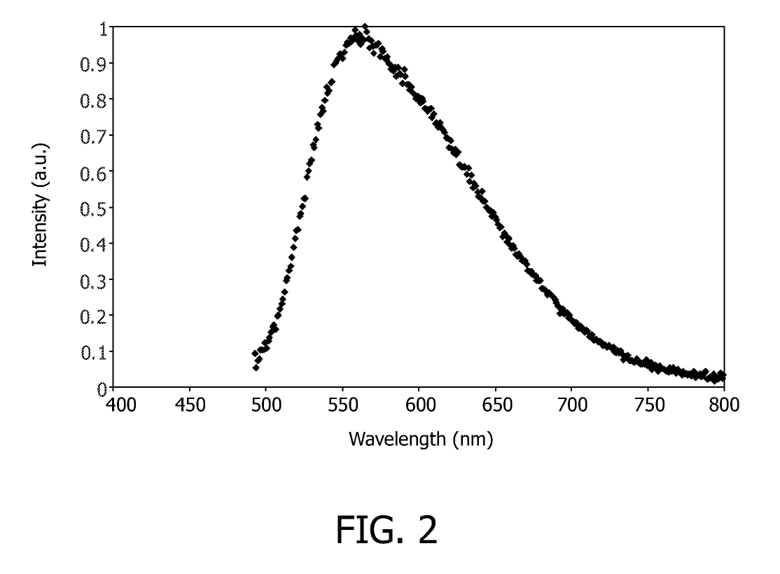

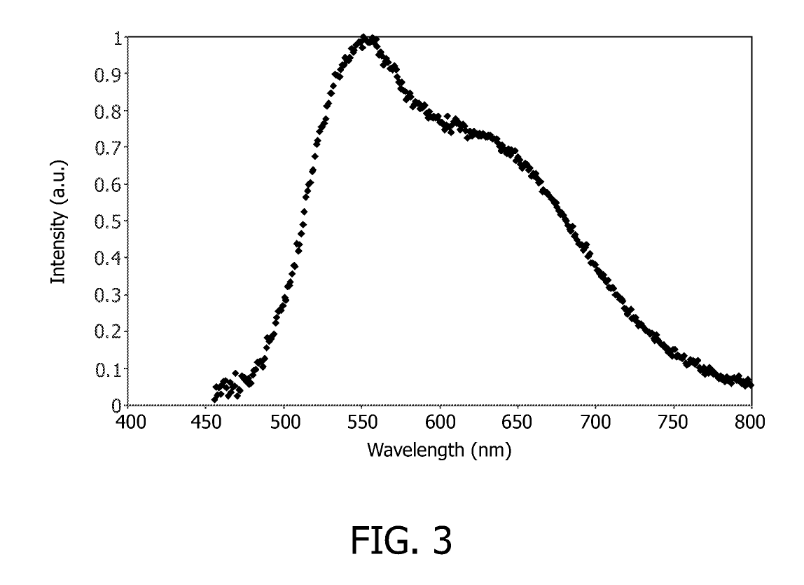

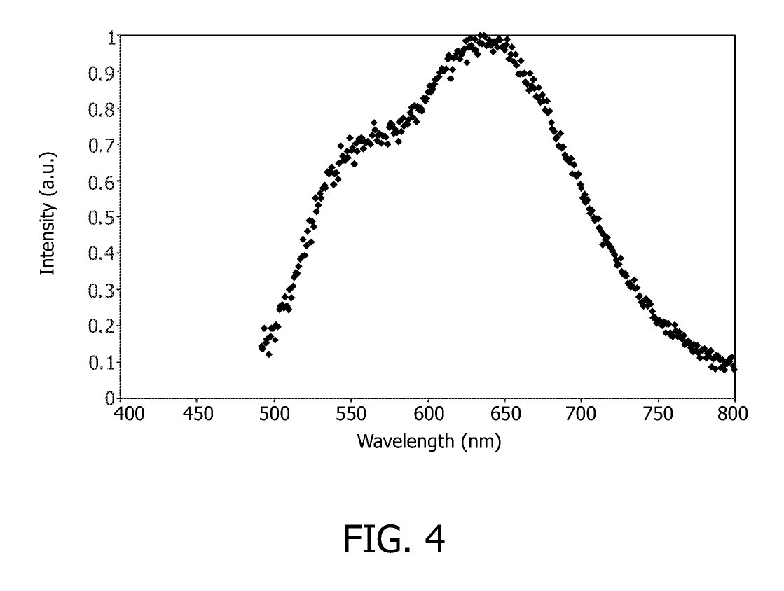

FIGS. 1 and 2 show emission spectra of the compositions according to Example I for 430 nm and 470 nm excitation, respectively, FIGS. 3 and 4 show the analogous spectra for Example II (i.e. FIG. 3 at 430 nm, FIG. 4 at 470 nm excitation). It can be clearly seen that all compositions exhibit a broad emission spectrum with a full width at half maximum of more than 100 nm.

The change of the emission spectrum with excitation wavelength is highly advantageous for a LED application, because color consistency is greatly improved compared to single-phase phosphor-converted LEDs. For example, if the blue emitting pump LED changes its spectral position, e.g. to longer wavelengths, the ceramic composite material also changes its spectrum in such a way that less green but more red emission is obtained. This spectral shift leads to a stabilization of the overall LED color point, which is highly advantageous for the systems and applications mentioned above.

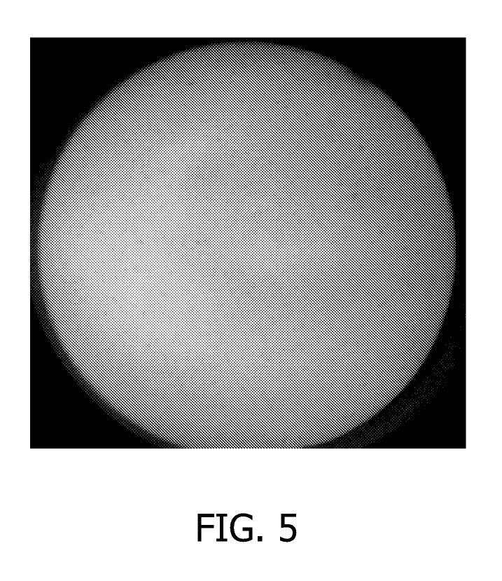

FIG. 5 shows a picture of a composite ceramic wafer of Example I under UV-light. It can be clearly seen that grains of the red light emitting phase of composition (Ca,Sr)(Si,Al)₂(N,O)₃:Eu are embedded in a green emitting matrix phase of composition (Sr,Ca)Si₂O₂N₂:Eu.

The particular combinations of elements and features in the above detailed embodiments are exemplary only; the interchanging and substitution of these teachings with other teachings in this and other patents/applications (incorporated herein by reference) are also expressly contemplated. As those skilled in the art will recognize, variations, modifications, and different implementations of what is described herein can occur to those of ordinary skill in the art without departing from the spirit and scope of the invention as claimed. Accordingly, the foregoing description is by way of example only and is not intended as limiting. The invention's scope is defined in the following claims and the equivalents thereto. Furthermore, reference signs used in the description and claims do not limit the scope of the invention as claimed.

1. Light emitting device, especially a LED comprising a ceramic composite material essentially of the composition M_{1-y}A₂₋ₓBₓO₂₋₂ₓN₂₊ₓ:Eu_{y}, where M is selected out of the group comprising Sr, Ca, Ba, Mg or mixtures thereof, A is selected out of the group comprising Si, Ge or mixtures thereof and B is selected out of the group comprising Al, B, Ga or mixtures thereof and x and y are independently selected from >0 to ≦1.

2. The light emitting device of claim 1, wherein the composite material comprises at least one amber to red emitting phase and at least one cyan to green emitting phase.

3. The light emitting device of claim 1, x is ≦0.6.

4. The light emitting device of claim 1, wherein the composite material comprises a phase of composition M(A,B)₂(O,N)₃:Eu and a phase of composition MA₂O₂N₂:Eu.

5. The light emitting device of claim 1, wherein the at least one amber to red emitting phase and/or at least one cyan to green emitting phase are essentially present in the composite material in form of ceramic grains to form a polycrystalline structure.

6. The light emitting device of claim 1, wherein the d₅₀ of the grains of the at least one amber to red emitting phase and/or of the at least one cyan to green emitting phase is in the range of ≧1 μm to ≦50 μm.

7. The light emitting device of claim 1, wherein the average grain size of the grains of the at least one amber to red emitting phase is larger than the average grain size of the grains of the at least one cyan to green emitting phase.

8. The light emitting device of claim 1, wherein the emission maximum of the ceramic composite material is in the range of ≧520 nm to ≦650 nm.

9. The light emitting device of claim 1, wherein the half-width of the emission band of the composite material in the visible wavelength range is in the range of ≧90 nm to ≦190 nm.

10. A system comprising a light emitting device according to claim 1, the system being used in one or more of the following applications:
Office lighting systems
household application systems
shop lighting systems,
home lighting systems,
accent lighting systems,
spot lighting systems,
theater lighting systems,
fiber-optics application systems,
projection systems,
self-lit display systems,
pixelated display systems,
segmented display systems,
warning sign systems,
medical lighting application systems,
indicator sign systems, and
decorative lighting systems
portable systems
automotive applications
green house lighting systems
